(19) United States
(12) Patent Application Publication
(10) Pub. No.: US 2008/0252204 A1
(43) Pub. Date: Oct. 16, 2008

(54) Organic Electroluminescence Device and Manufacturing Method of the Same

(75) Inventors: Ayako Yoshida, Saitama (JP); Akira Hirasawa, Saitama (JP); Satoshi Miyaguchi, Saitama (JP)

Correspondence Address: DRINKER BIDDLE & REATH (DC), 1500 K STREET, N.W., SUITE 1100, WASHINGTON, DC, 20005-1209, US

(73) Assignee: PIONEER CORPORATION, Tokyo (JP)

(21) Appl. No.: 11/887,411

(22) PCT Filed: Mar. 30, 2006
(86) PCT No.: PCT/JP2006/307278

§ 371 Date: Nov. 30, 2007

(30) Foreign Application Priority Data
Mar. 31, 2005 (JP) 2005-102708

(51) Int. Cl. H01L 51/54; B32B 38/16

(52) U.S. Cl. 313/504; 156/281; 156/273.3

(57) ABSTRACT

An organic EL device of top emission type having a structure of a transparent conductive layer on a metal reflecting layer, and particularly an organic EL device having a high luminance with the stability capable of maintaining the high luminance over the long period of time is provided. The organic EL device includes a metal electrode layer serving as a metal reflecting film, a transparent conductive layer, an organic functional layer having an organic EL layer, and a transparent electrode layer which are successively laminated on a substrate, and a formation area of the metal electrode layer resides inside a protection area where the transparent conductive layer is formed on the substrate.

### TECHNICAL FIELD

The present invention relates to an organic electroluminescence device (herein after referred to as an organic EL device), and more particularly to an organic EL device of a top emission type having a high luminance.

### BACKGROUND ART

An organic EL device having a multi-layer structure may be formed by sandwiching a light emitting layer of organic EL material between a pair of electrode layers. When voltage is applied across this pair of electrode layers, a hole and an electron are recombined in the light emitting layer to emit a light. In order to take out the light generated inside the light emitting layer from the device, at least one of the electrode layers provided on a front side of the device needs to be formed of a transparent material so that the light can pass through the electrode layer to the outside. For example, Japanese Patent Kokai No. 4-328295 discloses an organic EL device having a transparent electrode layer, a light emitting layer and a metal electrode layer formed in this order on a transparent substrate made of glass. The light generated in the light emitting layer is taken out from the device through the transparent electrode layer and the glass substrate. Further, Japanese Patent Kokai No. 2003-272855 discloses an organic EL device having a metal electrode layer, a light emitting layer and a transparent electrode layer formed in this order on a substrate. The light generated in the light emitting layer is taken out through the transparent electrode layer that is provided on the opposite side of the light emitting layer from the substrate. In the following description, the former type of the device having the feature to take out the light in a direction opposite to the laminate forming direction is called a bottom emission type, whereas the latter type of the device having the feature to take out the light in the same direction as the laminate forming direction is called a top emission type. Generally, an electron injection layer and an electron transport layer or the like may be suitably provided between the cathode and the light emitting layer for efficiently introducing electrons into the light emitting layer. On the other hand, a hole transport layer and a hole injection layer or the like may be suitably provided between the anode and the light emitting layer for efficiently introducing holes into the light emitting layer. In the following description, a term “organic functional layer” is used for a layered stack including the indispensable organic EL light emitting layer and optional layers such as the electron injection layer, the electron transport layer, the hole transport layer and so on.

A practical example using the above described organic EL device is an organic EL display. As shown in FIG. 1, a display is configured by forming a TFT 102 on a glass substrate 101, and then forming an organic EL device 103 thereon. The organic EL device 103 is configured by sandwiching an organic functional layer 105 containing an organic EL light emitting layer between one pair of electrode layers 104 and 106. A display 100a with an organic EL device of top emission type is more preferable than a display 100b with an organic EL device of bottom emission type because a light emitting portion of the organic EL device of the display 100a has a wider opening area that is independent from an opening area of the TFT 102. Accordingly, the organic EL device of the top emission type provides higher light emission. In other words, the display 100a using the organic EL device of top emission type consumes less electrical current through the device than the display 100b with the organic EL device of bottom emission type, and the display 100a still provides the same luminance as the display 100b. This feature makes it possible to increase a life span of the EL device. Since the electrical current can be decreased without lowering a specified luminance, the applied voltage to the device can be decreased, which makes it possible to prevent leakage within the EL device and reduce the power consumption.

On the other hand, there is known a method to further increase the luminous efficiency of the organic EL device of top emission type by inverting and guiding a part of the light traveling in a direction opposite to an outward emitting direction (a direction toward the substrate). Specifically, this method inverts the traveling direction of the part of the light generated in the organic functional layer to the outward emitting direction by using the metal electrode layer on the substrate. As disclosed in the patent document 2, there is known another method to increase the color purity of the device by taking out only the light having a desired wavelength range from the device. This effect is obtained by providing a transparent conductive layer on a metal reflecting layer to cause an interference under predetermined conditions between a light traveling in a direction toward the substrate and a light traveling in the outward emitting direction which are both generated in the organic functional layer.

It is an object of the present invention to provide an organic EL device of top emission type structure mentioned above having a transparent conductive layer on a metal reflecting layer, and particularly an organic EL device having high luminance and stability capable of maintaining this high luminance over a long period of time.

### DISCLOSURE OF THE INVENTION

According to one aspect of the present invention, there is provided an organic EL device including a metal electrode layer serving as a metal reflecting film, a transparent conductive layer, an organic functional layer having an organic EL layer, and a transparent electrode layer which are successively laminated on a substrate, wherein a formation area of the metal electrode layer resides inside a protection area where the transparent conductive layer is formed on the substrate.

With this arrangement, the formation area of the metal electrode layer resides inside the protection area where the transparent conductive layer is formed, which therefore makes it possible to suppress influence of metal components on the metal electrode layer.

According to another aspect of the present invention, there is another organic EL device including a metal electrode layer as a metal reflecting film, a transparent conductive layer, an organic functional layer containing an organic EL layer, and a transparent electrode layer which are successively laminated on a substrate, wherein the organic EL device having the transparent conductive layer and an insulation film adjacent to the transparent conductive layer on the substrate, and a formation area of the metal electrode layer resides inside a protection area where the transparent conductive layer and the insulation film are formed on the substrate.

With this arrangement, the formation area of the metal electrode layer resides inside the protection area where the transparent conductive layer and the insulation film are formed, which therefore makes it possible to suppress influence of metal components on the metal electrode layer.

An organic EL panel according to the present invention includes a plurality of organic EL devices described above.

Moreover, according to the present invention, there is provided a method for manufacturing an organic EL device, including a step of forming a metal electrode layer as a metal reflecting film on a substrate, a step of forming a transparent conductive layer on the metal electrode layer over the substrate, a step of cleaning a surface of the transparent conductive layer, a step of forming an organic functional layer on the transparent conductive layer, and a step of forming a transparent electrode layer on the organic functional layer, wherein a formation area of the metal electrode layer resides inside a protection area where the transparent conductive layer is formed on the substrate.

Also, according to the present invention, there is provided another method for manufacturing an organic EL device, including a step of forming a metal electrode layer as a metal reflecting film on a substrate, a step of forming an insulation layer adjacent to the metal electrode layer on the substrate, a step of forming a transparent conductive layer on the metal electrode layer and the insulation layer, a step of cleaning a surface of the transparent conductive layer, a step of forming an organic functional layer on the transparent conductive layer, and a step of forming a transparent electrode layer on the organic functional layer, wherein in a common area including a formation area of the organic functional layer on the substrate, a formation area of the transparent conductive layer and a formation area of the insulation layer, a formation area of the metal electrode layer is smaller than the common area and the formation area resides inside the common area.

Also, according to the present invention, there is provided another a method for manufacturing an organic EL device, including a step of forming a metal electrode layer as a metal reflecting film on a substrate, a step of forming a transparent conductive layer on the metal electrode layer, a step of forming an insulation layer adjacent to the metal electrode layer on the substrate, a step of cleaning the surface of the transparent conductive layer, a step of forming an organic functional layer on the insulation layer and the transparent conductive layer, and a step of forming a transparent electrode layer on the organic functional layer, wherein a formation area of the metal electrode layer resides inside a protection area where the transparent conductive layer and the insulation film are formed on the substrate.

### BRIEF DESCRIPTION OF THE DRAWINGS

FIG. 1 is a cross-sectional view of the conventional typical organic EL panel.

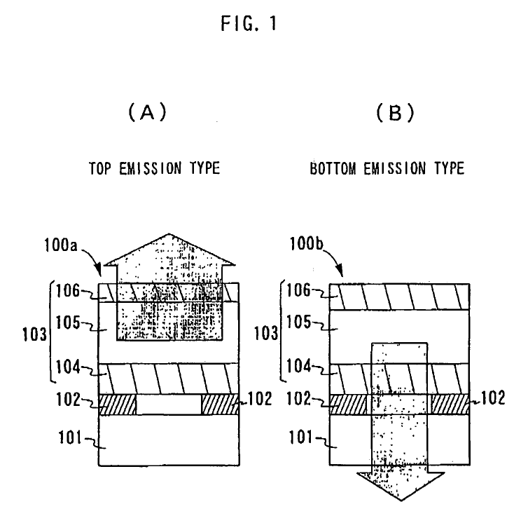

FIG. 2 is a cross-sectional view of an organic EL device according to a first embodiment of the invention.

FIG. 3 is an elevation view of an organic EL panel using the organic EL device according to the first embodiment of the invention.

FIG. 4 is a cross-sectional view of an organic EL device according to a second embodiment of the invention.

FIG. 5 is an elevation view of an organic EL panel using the organic EL device according to the second embodiment of the invention.

FIG. 6 is a cross-sectional view of a modification of the organic EL device according to the second embodiment of the invention.

FIG. 7 is a cross-sectional view of a modification of the organic EL device according to the second embodiment of the invention.

FIG. 8 is a cross-sectional view of a modification of an organic EL device according to a third embodiment of the invention.

### MODE FOR CARRYING OUT THE INVENTION

### First Embodiment

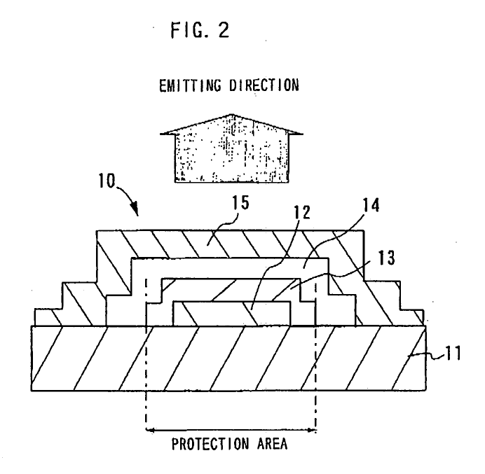

Referring to FIG. 2, the structure of an organic EL device 10 according to a first embodiment of the present invention will be herein after described.

A metal electrode layer 12 having a function of a reflecting film is arranged on a substrate 11 made of glass. A transparent conductive layer 13 made of ITO or the like is disposed over the metal electrode layer 12. The transparent conductive layer 13 fully covers the top and side parts of the metal electrode layer 12 within a protection area of the device, which will be described later. Further, an organic functional layer 14 and a transparent electrode layer 15 made of ITO or the like are laminated on the transparent conductive layer 13. Since the transparent conductive layer 13 surrounds the metal electrode layer 12, the organic functional layer 14 does not contact with the metal electrode layer 12. The organic functional layer 14 may be formed on only the top of the transparent conductive layer 13 to face the metal electrode layer 12. In the following description, a “protection area” designates an area on the substrate 11 where the transparent conductive layer 13 serving for the organic EL device 10 is formed. Specifically, the protection area is defined as, for example, an independent island-like area corresponding to one pixel on an emissive panel, or an area corresponding to one light emitting area as the panel. When an insulation film is formed adjacent to the transparent conductive layer 13, as will be described later, the “protection area” designates a formation area of the transparent conductive layer 13 serving for the device and the insulation film.

As shown in a cross-sectional view of the organic EL device 10 in FIG. 2, which is viewed from one direction, the metal electrode layer 12 does not directly contact with the organic functional layer 14 at least in the protection area. This feature can be viewed in any other cross sectional views viewed from any other directions. That is, the organic EL device 10 according to the first embodiment of the invention has the formation area (region) of the metal electrode layer 12 which is smaller than the formation area (region) of the transparent conductive layer 13 formed thereon, and is inside an area of the transparent conductive layer 13. Hence, the metal electrode layer 12 does not directly contact with at least the organic functional layer 14. In other words, the metal electrode layer 12 exists only under the transparent conductive layer 13 at least within the protection area of the device 10.

The organic EL device 10 of the above structure is of a top emission type in which the light generated in the organic functional layer is guided through the transparent electrode layer 15 to the outside of the device. Of the light generated in the organic functional layer 14, the light traveling. In a direction opposite to the outward emitting direction, viz., a direction toward the transparent conductive layer 13, passes through the transparent conductive layer 13 and reaches the metal electrode layer 12. Such light is reflected from the surface of the metal electrode layer 12, so that the travel direction is changed to a direction toward the organic functional layer 14. The light then passes through the organic functional layer 14 and is guided to the outside of the device, together with the light traveling in a direction from the organic functional layer 14 to the transparent electrode layer 15.

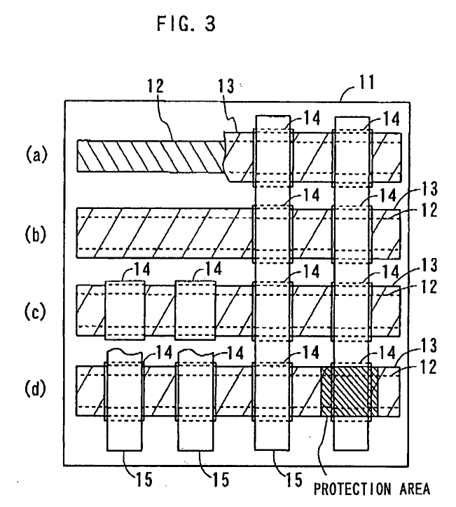

Other features of the organic EL device 10 according to the first embodiment of the invention will be shown in FIG. 3 together with the following description.

Referring to FIG. 3, a method for manufacturing the organic EL panel will be hereinafter described in which the panel includes a plurality of organic EL devices according to the first embodiment of the invention.

First of all, the substrate 11 made of glass is cleaned, and the metal electrode layers 12 made of aluminum are formed each to have a striped shape by vapor deposition or the like (see FIG. 3(a)). The material of the metal electrode layers 12 according to the first embodiment of the invention may be metal having electrical conductivity and a high reflectance of 50% or more to the light of a desired outward emitting wavelength among the lights generated in the organic functional layers 14 (light having emitting wavelength of the device). Such metal may be, for example, Al, Ag, Cu, Ni, Cr, Ti or Mo, or their alloy. Particularly, aluminum or silver, or their alloy is preferred for the light in the typical visible light region. Aluminum, silver, or their alloy is suitable for the material of the metal electrode layers 12 because they satisfy the above condition as the reflecting film. Furthermore, they are available at low cost and can be formed through a simple process such as vapor deposition. On the other hand, if these metals or metal ions from these metals are included in the organic functional layers 14, the light emitting characteristics of the device may be affected, which will be described later. The metal electrode layers 12 made of one of these materials perhaps produce projections when oxidized to degrade the reflection characteristics themselves. Also the metal electrode layers 12 made of one of these materials possibly deteriorate the surface property, due to migration during energization through the device, which causes leakage of the device. On the other hand, the present invention is suitable because these problems can be avoided which will be described later.

Next, the transparent conductive layers 13 made of ITO (indium tin oxide) are formed each having a striped shape on the metal electrode layers 12 by vapor deposition or the like (see FIG. 3(b)). Each of the transparent conductive layers 13 is formed each to have a predetermined thickness as a single layer or plural layers in order to take out only the light in the desired wavelength range from the device to increase the color purity, as described above. The width of the stripe of each transparent conductive layer 13 is larger than the width of the stripe of each metal electrode layer 12. The stripes of the transparent conductive layers 13 are formed to cover the metal electrode layers 12 respectively and extend over the substrate 11. That is, each of transparent conductive layers 13 in cooperation with the substrate 11 fully surrounds the top, bottom and side of the stripe of the metal electrode layer 12, and therefore the metal electrode layer 12 is not exposed to the outside.

The transparent conductive layers 13 may preferable be made of a material having an optical transparency to the light having desired outward emitting wavelength among the lights generated in the organic functional layers 14 and having excellent conductivity, such as ITO, IZO, IWO, ZnO, SnO. Particularly, ITO or IZO (indium zinc oxide) is preferable. It should be noted that the transparent conductive material such as ITO or IZO is suitable because it typically has a large work function and it excellently supply holes to the organic functional layer 14 when it is used as the anode. Thus, it is preferable that, when the transparent conductive layers 13 made of ITO or the like are formed as the anodes, a hole transport layer or a hole injection layer is arranged on a side adjacent to the transparent conductive layer 13. The hole transport layer or hole injection layer is a layer that belongs to each organic functional layer 14 to be provided on the positive electrode side.

The organic functional layers 14 are formed on the stripe-shaped transparent conductive layers 13 with a periodical interval there between by vapor deposition (see FIG. 3(c)). The organic functional layers 14 may be formed on only the transparent conductive layers 13 respectively, alternatively they may be formed to cover the tops and sides of the transparent conductive layers 13 and to expand over the substrate 11.

In order to increase the tight contactness between the transparent conductive layer 13 and the organic functional layer 14 and to increase the transfer efficiency of electric charges between the layers, the organic functional layers 14 should be formed after reliable cleaning of the surface of the transparent conductive layers 13. To clean the transparent conductive layers 13, an UV ozone cleaning method or a plasma cleaning method in a vacuum condition may be employed. It should be noted that the metal such as silver or aluminum or their alloy used for the metal electrode layers 12 as described above is easily oxidized and eroded by the UV ozone cleaning method or the plasma cleaning method. However, according to the first embodiment of the invention, the metal electrode layers 12 are not oxidized or eroded in a cleaning process because none of the metal electrode layers 12 is exposed to the cleaning environment. Accordingly, the metal electrode layers 12 can maintain the excellent characteristics as the electrode and the reflecting film. In addition, a cleaning medium is supplied from above the substrate 11 along the normal line thereof in the cleaning step. Therefore, in case that only the side face of each metal electrode layer 12 is not covered with the transparent conductive layer 13 during the cleaning step, it is preferable that at least the side part of each metal electrode layer 12 resides inside and under the transparent conductive layer 13. Alternatively, the organic functional layers 14 to be provided on the top of the transparent conductive layers 13 may be formed after removing a mask provided on the metal electrode layers 12 so as to prevent the metal electrode layers 12 from being exposed to the cleaning medium that is used for cleaning the transparent conductive layers 13.

On each transparent conductive layer 13 serving for the anode, a plurality of layers such as a hole transport layer or hole injection layer, an organic EL light emitting layer, and an electron transport layer are successively formed in this order for the organic functional layers 14 by vapor deposition. In the present invention, the organic functional layers 14 such as the hole transport layer, the hole injection layer, the light emitting layer and the electron transport layer may be made of any well-known materials respectively. For example, the material of the hole transport layer in contact with the transparent conductive layer 13 may be, but not limited to, an organic compound such as benzidine, oxadiazole, phthalocyanine, or triphenylamine.

Generally, physical properties of the organic compound used for the organic functional layer 14 is susceptible to metal or metal ion. The organic EL device of top emission type may be affected by metal or metal ion used for the metal electrode layer 12, because the organic functional layer 14 is provided above the metal electrode layer 12. According to the invention, each metal electrode layer 12 is embedded inside the transparent conductive layer 13 at least in the protection area so as not to expose the metal electrode layer 12 to the outside environment at the time of forming the organic functional layers 14. Therefore, the organic functional layers 14 can be formed without being affected by the metal electrode layers 12. Also, during the cleaning process for cleaning the surface of the transparent conductive layers 13, the metal electrode layers 12 are not exposed to the cleaning environment for the transparent conductive layers 13 on which the organic functional layers 14 are formed. Accordingly, no metal dust of the metal electrode layers 12 is produced in the cleaning process, and no oxidization occurs on the surfaces of the metal electrode layers 12. Therefore, it becomes possible to prevent such metal dusts from sticking onto the surfaces of the transparent conductive layers 13 or from being included in the organic functional layers 14 which are formed by vapor-deposition. It also becomes possible to avoid emission leakage of the device due to deterioration of a reflection power of the metal electrode layer 12 which is caused by oxidization or deterioration of surface property or migration during energization of the device.

The organic functional layer 14 is not in direct contact with the metal electrode layer 12. Hence, the metal or metal ion in the metal electrode layer 12 does not influence the organic functional layer 14.

With the above described arrangement, the organic EL panel according to the invention has features of high luminance and less age deterioration.

Lastly, the transparent electrode layers 15 are formed each to have a striped shape over a plurality of organic functional layers 14 by vapor deposition (see FIG. 3(d)).

As described above, in the first embodiment of the invention, the formation area of each metal electrode layer 12 is smaller than the protection area, and the formation area resides inside the protection area.

### Second Embodiment

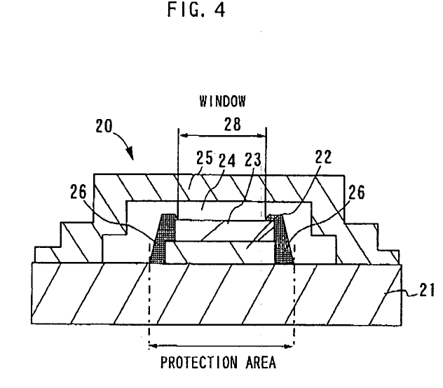

Referring to FIG. 4, the structure of an organic EL device 20 according to a second embodiment of the present invention will be herein after described.

A metal electrode layer 22 having a function of a reflecting film is arranged on a substrate 21 made of glass. A transparent conductive layer 23 made of ITO or the like is arranged on the metal electrode layer 22. Insulation films 26 made of SiO₂ or the like are arranged on a substrate 21 to fully cover at least the side faces of the metal electrode layer 22 and the transparent conductive layer 23. An edge portion of each insulation film 26 expands to a top portion of the transparent conductive layer 23. With this arrangement, a window 28 is formed between the edge portions of the insulation films 26 on the top of the transparent conductive layer 23. An organic functional layer 24 and a transparent electrode layer 25 made of ITO or the like are laminated on the transparent conductive layer 23 and the insulation films 26. Specifically, the transparent conductive layer 23 and the organic functional layer 24 contact to each other via the window 28 defined by the insulation films 26.

FIG. 4 showing one cross-sectional view of the organic EL device 20 viewed from one direction illustrates such feature that the metal electrode layer 22 is separated from the organic functional layer 24 by the insulation films 26 and the transparent conductive layer 23 at least within a protection area of the device 20. This feature can be viewed in any other cross-sectional views viewed from any other directions. Specifically, the metal electrode layer 22 and the organic functional layer 24 do not directly contact to each other.

This organic EL device 20 is of a top emission type similar to the first embodiment in which the light emitted in the organic functional layer 24 is guided to the outside through the transparent electrode layer 25. Transfer of the electric charges from the transparent conductive layer 23 to the organic functional layer 24 is performed via the window 28 defined by the insulation films 26. Among the lights generated in the organic functional layer 24, the light traveling in a direction toward the transparent conductive layer 23 passes through the window 28 and the transparent conductive layer 23, and reaches the metal electrode layer 22. Herein, the light is reflected and the travel direction is changed to a direction toward the organic functional layer 24. The reflected light passes through the window 28 again and is guided to the outside of the device together with another light generated in the organic functional layer 24 and traveling in a direction toward the transparent electrode layer 25. Since the path of the light taken out from the device is restricted by the window 28, the edge of the light is clear. This feature of the organic EL device is particularly suitable for application of the organic EL panel.

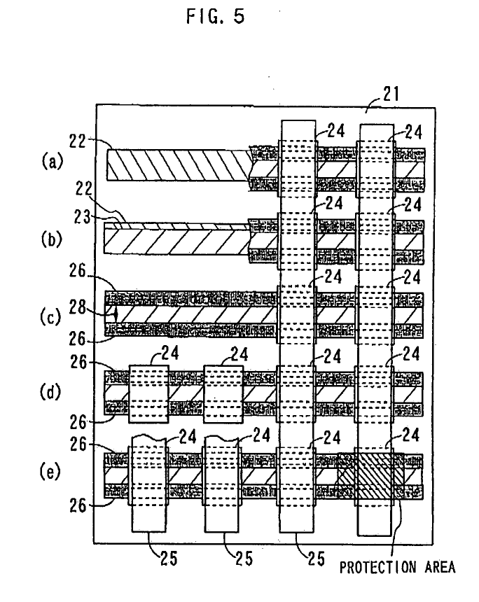

Referring to FIG. 5, one method for manufacturing an organic EL panel including the organic EL device according to the second embodiment of the invention will be described below.

First of all, the substrate 21 made of glass is cleaned, and the metal electrode layers 22 made of aluminum or the like are formed thereon to have a striped shape by vapor deposition or the like (see FIG. 5(a)). The transparent conductive layers 23 made of ITO are formed each to have a striped shape on the metal electrode layers 22 by vapor deposition or the like (see FIG. 5(b)). It is preferable that the width of the stripe of the transparent conductive layer 23 is approximately the same as that of the metal electrode layer 22. It is however unnecessary that the center lines of both strips coincide to each other. As shown in FIG. 5, the center lines of both strips may be arranged to have a slight offset. Refer to the first embodiment for the material of the metal electrode layer 22.

The insulation films 26 made of SiO₂ or the like are formed on the substrate 21 along the side faces of the metal electrode layers 22 and the transparent conductive layers 23 (see FIG. 5(c)). One edge portion of each insulation film 26 expands to the top of the transparent conductive layer 23, such that the window 28 is formed to expose the top of the transparent conductive layer 23 to the outside.

The surfaces of the transparent conductive layers 23 are cleaned via the window 28 by using a cleaning process such as an UV ozone cleaning method or a plasma cleaning method in a vacuum condition. According to the second embodiment of the present invention, each metal electrode layer 22 is surrounded by the transparent conductive layer 23 and the insulation layer 26, and is not exposed to the outside environment, and therefore the metal electrode layer 12 is not oxidized nor eroded in the cleaning process. Accordingly, the metal electrode layers 22 can maintain the excellent characteristics as the electrode and the reflecting film similar to the first embodiment.

The organic functional layers 24 are arranged on the transparent conductive layers 23 and the insulation films 26 (see FIG. 5(d)). Lastly, the transparent electrode layers 25 are formed each to have a striped shape over the organic functional layers 24 consisting of a plurality of sections by vapor deposition (see FIG. 5(e)).

For the details of the materials in the above description, refer to the first embodiment.

In each device on the substrate 21, a formation area of the metal electrode layer 22 of the second embodiment of the present invention is smaller than a protection area that is a formation area of the transparent conductive layer 23 and the insulation films 26, and thus the formation area resides inside a common area thereof. Specifically, since the metal electrode layer 22 is surrounded by the transparent conductive layer 23 and the insulation films 26, the organic functional layer 24 and the metal electrode layer 22 do not contact to each other in a light emitting portion. Therefore, the metal or metal ion in the metal electrode layer 22 does not influence the organic functional layer 24 which is similar to the first embodiment. Further, since the metal electrode layer 22 is not exposed to the outside environment during the cleaning process for cleaning the surface of the transparent conductive layer 23, it is possible to reduce age deterioration of the device which is similar to the first embodiment.

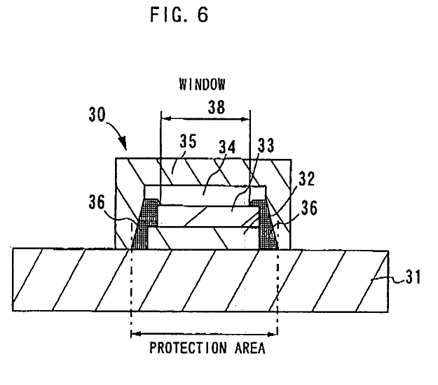

Referring to FIG. 6, a modification of an organic EL device 30 according to the second embodiment of the present invention will be herein after described.

A metal electrode layer 32 having a function of a reflecting film is arranged on a substrate 31 made of glass. A transparent conductive layer 33 made of ITO or the like is arranged on the metal electrode layer 32. Insulation films 36 made of SiO₂ or the like are arranged on the substrate 31 to fully cover the side faces of the metal electrode layer 32 and the transparent conductive layer 33. The insulation films 36 cover the side face of the transparent conductive layer 33, and the insulation films 36 further cover an area beyond the side faces such that an edge portion of each insulation film 36 reaches a top portion of the transparent conductive layer 33. With this arrangement, a window 38 is formed by the edge portions of the insulation films 36 on the top of the transparent conductive layer 33. An organic functional layer 34 is formed on the transparent conductive layer 33 and the insulation films 36 to fill up the window 38 defined by the insulation films 36. A transparent electrode layer 35 is formed on the organic functional layer 34. A cross-sectional view of the organic EL device 30 of FIG. 6 illustrates such feature that the metal electrode layer 32 is not in direct contact with the organic functional layer 34 by providing the insulation films 36 and the transparent conductive layer 33 there between in the protection area where the transparent conductive layer 33 and the insulation films 36 are formed. This feature can be viewed in any other cross sectional views viewed from any other directions.

As described above, in this modification of the second embodiment of the present invention, the formation area of the metal electrode layer 32 is smaller than the protection area, and thus the formation area resides inside the protection area. The organic EL device 30 having the above described structure has similar features as the device of the second embodiment. In addition, it is possible to increase the electrical current efficiency and reduce the material cost because the organic functional layer 34 is formed within a smaller area.

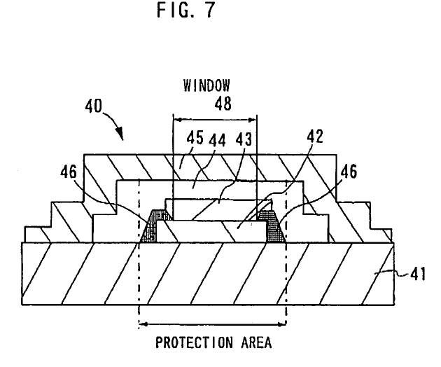

Referring to FIG. 7, another modification of an organic EL device 40 according to the second embodiment of the present invention will be herein after described.

A metal electrode layer 42 having a function of a reflecting film is arranged on a substrate 41 made of glass. Insulation films 46 made of SiO₂ or the like are formed on the substrate 41 to fully cover the side of the metal electrode layer 42, and an edge portion of each insulation film 46 expands to the top of the metal electrode layer 42. With this arrangement, the edge portions of the insulation films 46 define a window 48 smaller than the metal electrode layer 42 on the top thereof. A transparent conductive layer 43 made of ITO or the like is arranged on the metal electrode layer 42 to fully cover the window 48. An organic functional layer 44 and a transparent electrode layer 45 made of ITO or the like are laminated on the transparent conductive layer 43 and the insulation films 46. A cross-sectional view of the organic EL device 40 in FIG. 7 illustrates such feature that the metal electrode layer 42 is separated from the organic functional layer 44 at least in the protection area by the insulation films 46 and the transparent conductive layer 43. Consequently, the metal electrode layer 42 is not in direct contact with the organic functional layer 44. This feature can be viewed in any other cross-sectional views viewed from any other directions.

As described above, according to the modification of the second embodiment of the present invention, a formation area of the metal electrode layer 42 is smaller than the protection area on the substrate 41, and thus the formation area resides inside the protection area. The organic EL device 40 of such structure has similar functional features as the second embodiment.

### Third Embodiment

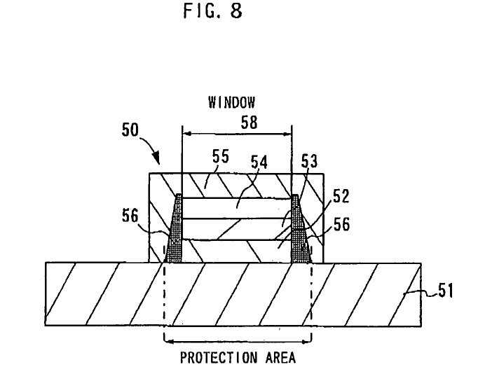

Although the organic EL device and its manufacturing method have been described based on a passive matrix type panel in the above embodiments, they can be applied to an active matrix type panel. Referring now to FIG. 8, the structure of an organic EL device 50 according to a third embodiment of the present invention will be herein after described as one embodiment of the active matrix type panel.

A metal electrode layer 52 having a function of a reflecting film is formed on a TFT substrate 51. A transparent conductive layer 53 made of ITO or the like is arranged on the metal electrode layer 52. Insulation films 56 made of SiO₂ or the like are arranged on the TFT substrate 51 to fully cover and surround the side faces of the metal electrode layer 52 and the transparent conductive layer 53. Particularly, the height of each insulation film 56 from the surface of the TFT substrate 51 is at least greater than the distance between the surface of the TFT substrate 51 and the surface of the transparent conductive layer 53. Accordingly, an annular window 58 is formed along the edge portion of the transparent conductive layer 53.

The surface of the transparent conductive layer 53 is cleaned via the window 58 by a cleaning process such as an UV ozone cleaning method or a plasma cleaning method in a vacuum condition. According to the third embodiment of the present invention, the metal electrode layer 52 is surrounded by the transparent conductive layer 53 and the insulation layer 56, and is not exposed to the outside environment, and therefore the metal electrode layer 52 is prevented from being deteriorated. Accordingly, the metal electrode layer 52 can maintain the excellent characteristics as the electrode and the reflecting film which are similar to the first embodiment.

The organic functional layers 54 are laminated successively on the transparent conductive layer 53 to fill up the window 58. Emitting sections of the device emitting red and green colors in the active matrix type panel may be formed by an ink jet method. Specifically, a discharge solution prepared by dissolving an organic luminous material into a solution is discharged into an area surrounded by the window 58 on the organic functional layer 54 by way of an ink jet, which makes it possible to form a light emitting layer of the organic functional layer 54. The details of this technique are well known to a person skilled in the art and thus not particularly described herein.

A subsequent process is similar to the process described above, and thus the description thereof is omitted.

1. An organic electroluminescence device including a metal electrode layer serving as a metal reflecting film, a transparent conductive layer, an organic functional layer having an organic EL electroluminescence layer, and a transparent electrode layer which are successively laminated on a substrate,
wherein a formation area of said metal electrode layer resides inside a protection area where said transparent conductive layer is formed on said substrate;
wherein a side face of the metal electrode layer is not covered with the transparent conductive layer; and
wherein at least a side part of the metal electrode layer resides inside and under the transparent conductive layer.

2. The organic electroluminescence device according to claim 1, wherein said metal electrode layer is made of aluminum, silver or alloy thereof.

3. The organic electroluminescence device according to claim 2, wherein said transparent conductive layer is made of ITO or IZO.

4. An organic electroluminescence device including a metal electrode layer as a metal reflecting film, a transparent conductive layer, an organic functional layer having an organic electroluminescence layer, and a transparent electrode layer which are successively laminated on a substrate,
wherein said organic electroluminescence device having said transparent conductive layer and an insulation film adjacent to said transparent conductive layer on said substrate,
wherein a formation area of said metal electrode layer resides inside a protection area where said transparent conductive layer and said insulation film are formed on said substrates and
wherein an edge portion of said insulation film is located between said metal electrode layer and said transparent conductive layer so that a window defined by the edge portion of said insulation film is formed on said metal electrode layer.

5. (canceled)

6. The organic electroluminescence device according to claim 4, wherein a part of said insulation film is located between sand transparent conductive layer and said organic functional layer.

7. The organic electroluminescence device according to claim 4, wherein said metal electrode layer is made of aluminum, silver or alloy thereof.

8. The organic electroluminescence device according to claim 4, wherein said transparent conductive layer is made of ITO or IZO.

9. An organic electroluminescence panel comprising a plurality of organic electroluminescence devices according to claim 1.

10. A method for manufacturing an organic electroluminescence device, comprising:
a step of forming a metal electrode layer as a metal reflecting film an a substrate;
a step of forming a transparent conductive layer on said metal electrode layer in such a manner that a side face of the metal electrode layer is not covered with the transparent conductive layer so that at least a side part of the metal electrode layer resides inside and under the transparent conductive layer;
a step of cleaning a surface of sand transparent conductive layer;
a step of forming an organic functional layer on said transparent conductive layer; and
a step of forming a transparent electrode layer on said organic functional layer;
wherein a formation area of said metal electrode layer resides inside a protection area where said transparent conductive layer is formed on said substrate.

11. The method for manufacturing the organic electroluminescence device according to claim 10, wherein said metal electrode layer is made of aluminum, silver or alloy thereof.

12. The method for manufacturing the organic electroluminescence device according to claim 11, wherein said transparent conductive layer is made of ITO or IZO, and said cleaning step is performed by an UV ozone cleaning method or a plasma cleaning method.

13. A method for manufacturing an organic electroluminescence device, including:
a step of forming a metal electrode layer as a metal reflecting film on a substrate;
a step of forming an insulation film on said metal electrode layer and said substrate in such a manner that an edge portion of said insulation film is located in said metal electrode layer so that a window defined by the edge portion of said insulation film is formed on said metal electrode layer;
a step of forming a transparent conductive layer on said metal electrode layer and said insulation film in such a manner that the edge portion of said insulation film is located between said metal electrode layer and said transparent conductive layer;
a step of cleaning a surface of said transparent conductive layer;
a step of forming an organic functional layer on said transparent conductive layer; and
a step of forming a transparent electrode layer on said organic functional layer;
wherein a formation area of said metal electrode layer resides inside a protection area where said transparent conductive layer and said insulation film are formed on said substrate.

14. (canceled)

15. The method for manufacturing the organic electroluminescence device according to claim 13, wherein said metal electrode layer is made of aluminum, silver or alloy thereof.

16. The method for manufacturing the organic electroluminescence device according to claim 15, wherein said transparent conductive layer is made of ITO or IZO, and said cleaning step is performed by an UV ozone cleaning method or a plasma cleaning method.

17-20. (canceled)
